(19) United States
(12) Patent Application Publication
(10) Pub. No.: US 2025/0354289 A1
(43) Pub. Date: Nov. 20, 2025

(54) PROCESS FOR THE PRODUCTION OF PRECIPITATED SINGLE PHASE CRYSTALLINE 1-D NANOSCALED CALCITE

(71) Applicant: University of South Africa, Pretoria (ZA)

(72) Inventors: Malek MAAZA, Pretoria (ZA); Hamza Elsayed Ahmed MOHAMED, Pretoria (ZA)

(21) Appl. No.: 19/282,477

(22) Filed: Jul. 28, 2025

Related U.S. Application Data
(63) Continuation of application No. PCT/ZA2024/050005, filed on Jan. 26, 2024.

(30) Foreign Application Priority Data
Jan. 26, 2023 (ZA) 2023/01095

(51) Int. Cl. C30B 7/14; B82Y 40/00; C30B 29/22

(52) U.S. Cl. CPC C30B 7/14; B82Y 40/00; C30B 29/22

(57) ABSTRACT

A process is provided for the production of precipitated single-phase crystalline 1-D nanoscaled calcite (CaCO3). This process utilizes natural plant extracts, specifically from Hyphaene thebaica fruit, as a chelating agent. The method involves combining a source of calcium cations, typically calcium chloride (CaCl2), with a source of carbon dioxide (CO2) in a solvent of water (H2O). The natural extract acts as a bio-catalyst, facilitating the formation of crystalline CaCO3 with unique properties. The process is distinguished by its avoidance of synthetic chelating agents, pH control chemicals, and additional thermal treatments, making it a green and sustainable approach to CaCO3 production. The calcite demonstrates notable shape anisotropy and elevated porosity, attributes that are beneficial in various applications.

### CROSS REFERENCE TO RELATED APPLICATIONS

This application is a continuation of International Patent Application No. PCT/ZA2024/050005, filed on Jan. 26, 2024, which claims priority to South African Patent Application No. 2023/01095, filed Jan. 26, 2023, the contents of each of which are incorporated by reference herein.

### FIELD OF THE INVENTION

The present invention relates to a process for the production of precipitated single phase crystalline 1-D nanoscaled calcite CaCO₃. The present invention further relates to the use of the product as obtained from the process in cement binder applications, as a nano-fertilizer, a drug carrier in the health sector or for use as a white pigment.

### BACKGROUND

Within the pressing urgency of climate change, decarbonization processes and related technologies (CO2 sequestration, CO2 cycling, CO2 conversion are extensively investigated in view of reducing the CO2 global footprint. Cabonates (XCO₃) in general and Calcium Carbonate (CaCO₃) specifically could be effectively produced by harnessing atmospheric CO2 and converting it into a valuable final product that is of economic value such as a major cement component, white pigment, green fertilizer or a drug carrier in the health sector & in dentistry.

Calcium Carbonate makes up almost 4% of the Earth's crust and has been studied extensively due to its importance in bio-mineralisation in natural systems, including alkalinity generation, and biogeochemical cycling of elements. Natural Calcium Carbonate which forms through biomineralization process has three known natural crystalline forms, Vaterite, Calcite, and Aragonite, the first one being a metastable polycrystal. However, Vaterite has attracted the attention of the scientific community in view of its peculiar optical and biochemical properties. The two other structures of CaCO₃ i.e., the Aragonite and Calcite forms of CaCO₃ play a pivotal role in various strategic industries, specifically cement, paint & coatings sectors.

From the synthesis viewpoint, and in addition to the established physical and chemical processes as well as the natural biomimicry for the fabrication of CaCO₃, there is a fast growing methodology consisting of bio-engineering such a compound in a green and sustainable approach.

U.S. Pat. No. 4,824,653: Discusses improving the color of calcium carbonate by treating limestone slurry with synthetic chelating agents like EDTA. This method does not utilize natural plant extracts as chelating agents and focuses on pH in the base range, differing from the process in the invention in question.

WO 96/15985: Describes a process for purifying calcium carbonate using a chelating agent and carbon dioxide treatment. The process reduces iron content in calcium carbonate but does not incorporate natural plant extracts as chelating agents, contrasting with the invention in question.

WO 98/24725: Claims a process for preparing calcium carbonate under controlled pH, producing calcium carbonate with lower non-calcium metal concentrations. Unlike the invention in question, this process does not use natural plant extracts for chelation.

WO 2014/147010: Most relevant to the current invention, it describes precipitated calcium carbonate in nanofiber or nanochain forms. Key differences include the absence of natural plant extracts as chelating agents and the use of an aqueous medium in the process.

In view of the above, this disclosure provides an improved environmentally friendly bio-engineering non energy-intensive process for the biosynthesis of single phase crystalline nano-scaled CaCO₃ with a significant shape anisotropy and elevated porosity using a natural extract of, for example, the Hyphaene thebaica fruit, Hyphaene being a type of palm tree with edible oval fruit. While the validation was confirmed using Hyphaene thebaica, other natural extracts can be used.

### SUMMARY

According to a first aspect of the invention, the invention relates to a process for the production of precipitated single phase crystalline 1-D nanoscaled Calcite (CaCO₃), said process including;
providing a source of Calcium cations
providing a source of Carbon dioxide (CO₂),
providing a solvent in the form of water (H₂O),
providing a natural extract obtained from a plant species as a chelating agent, and
extracting the precipitate.

In one embodiment the Calcium cations may be obtained from Calcium Chloride (CaCl₂)),but other Ca precursors could, a priori, be used too,

In yet another embodiment the natural extract obtained from a plant species may be Hyphaene thebaica fruit.

In one embodiment of the invention, 3.32 g of Calcium Chloride (CaCl₂) M=110.98 g) were added to 100 mL filtered extract solution and stirred for 24 hours at room temperature with gentle stirring.

Furthermore, adding CO₂ via bubbling and allowing the precipitate to settle down.

Still further, collecting the precipitate by centrifugation for between 10 and 30 minutes, ideally for 20 min at a range of between 3,000 rpm to 5000 rpm in an ideal embodiment 4,000 rpm.

Yet further, the precipitate was washed thrice in dH2O and by subsequent centrifugation for between 5 and 15 minutes, ideally 10 min at a range of between 3,000 rpm to 5000 rpm in an ideal embodiment 4,000 rpm.

It is further important to note that non of the following additional aspects were used to enable the successful the production of precipitated single phase crystalline 1-D nanoscaled Calcite (CaCO3) being that no additional catalyst was used nor additional chemicals for pH control, furthermore no additional thermal treatment during or after the process of biosynthesis,

According to a second aspect of the invention, the use of the product as obtained from the process above for use in in cement binder applications.

According to a third aspect of the invention, the use of the product as obtained from the process above for use as a nano-fertilizer.

According to a fourth aspect of the invention, the use of the product as obtained from the process above for use a drug carrier or dentistry compound in the health sector.

According to a fifth aspect of the invention, the use of the product as obtained from the process above for use as a drug carrier in the health sector.

According to a sixth aspect of the invention, the use of the product as obtained from the process above for use as a white pigment.

According to a seventh aspect of the invention, the use of the product as obtained from the process, wherein an emulsion stable in water when applied to the surfaces of plants provides exceptional sun blocking characteristics.

In one example the product may be diluted in a suitable amount of water and applied to a potentially affected area with a suitable spraying device.

### BRIEF DESCRIPTION OF THE DRAWING

A process to produce precipitated single phase crystalline 1-D nano-scaled Calcite in accordance with the invention will now be described by way of the following, non-limiting examples with reference to the accompanying drawing. In the drawings:

FIG. 1(a)-1(f) show a typical High Resolution Transmission Electron Microscopy (HRTEM) and Selected Area Electron Diffraction (SAED) of the bio-engineered CaCO₃ of the present invention;

FIG. 2 shows a typical Scanning Electron Spectroscopy (EDS) profile of the bio-engineered nano-scaled CaCO₃ of the present invention;

FIG. 3(a) shows a Thermo-Gravimetry Analysis (TGA) of the bio-engineered nano-scale CaCO3 within the thermal range of 25-850° C. of the present invention;

FIG. 3(b) shows the corresponding Differential Scanning calorimetry (DSC) profile within the thermal range of 25-900° C. of the present invention;

FIG. 4(a) shows results of room temperature Fourier Transform Infrared spectroscopy spectrum of the bioengineered nano-scale CaCO₃ within the spectral range of 400-4000 cm⁻¹ of the present invention;

FIG. 4(b) shows an exploded view on the spectral region of 400-1000 cm⁻¹ reporting the characteristic Raman active modes of Calcite (CaCO₃) at 288 cm⁻¹ (L_{Calcite}) and 161 cm⁻¹ (T_{Calcite});

FIG. 5(a) shows room temperature Raman spectrum of the bio-engineered CaCO₃ nanoparticles within the range of 0-1200 cm⁻¹ of the present invention;

FIG. 5(b) shows an exploded view on the spectral region of 100-370 cm⁻¹ reporting the Ca—O characteristic vibrational mode of Calcite Ca CO₃ of the present invention;

FIG. 6 shows room temperature photoluminescence of the bio-synthesized nanoscaled CaCO3 as well as the intermediary product of Ca(OH)₂ and the initial precursor CaCl₂) in accordance with the present invention;

FIGS. 7(a)-7(d) show the Θ-2Θ X-rays diffraction spectra within the angular range of (a) 20-50 degree and (b) 55-85 degrees, (c) Full XRD profile with the MAUD simulation and (d) Proposed Calcite crystallographic structure of the bio-engineered CaCO₃ 1-D nanoparticles in accordance with the present invention;

FIG. 8(a) shows a standard diffuse reflectance spectrum under normal incidence of the bio-engineered CaCO₃ 1-D nanoparticles within the spectral range of 200-1000 nm; highlighting the elevated reflectivity within the VIS & NIR solar spectrum.

FIG. 8(b) shows an exploded view of FIG. 8(a) which corresponds on the UV-Bleu spectral region of 200-345 nm;

FIGS. 9(a)-9(c) show the evolution versus the bio-engineered CaCO₃ 1-D nanoparticles using nutrient concentration of (a) the average of plant's height, (b). the average number of leaves and (c) the average days to flowering relatively to the control sample; highlighting the efficacy as a potential green fertilizer.

FIGS. 10(a)-10(c) show multi-scale porosity in the bio-engineered CaCO₃ 1-D nanoparticles.

### DETAILED DESCRIPTION OF THE PREFERRED EMBODIMENTS

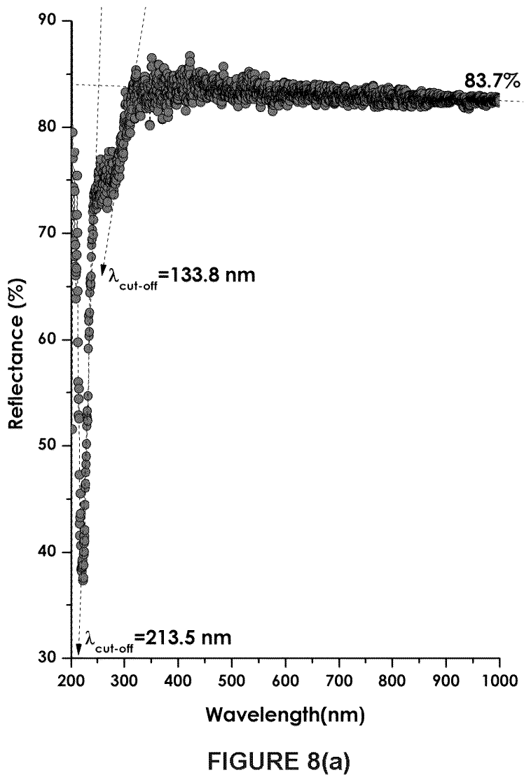

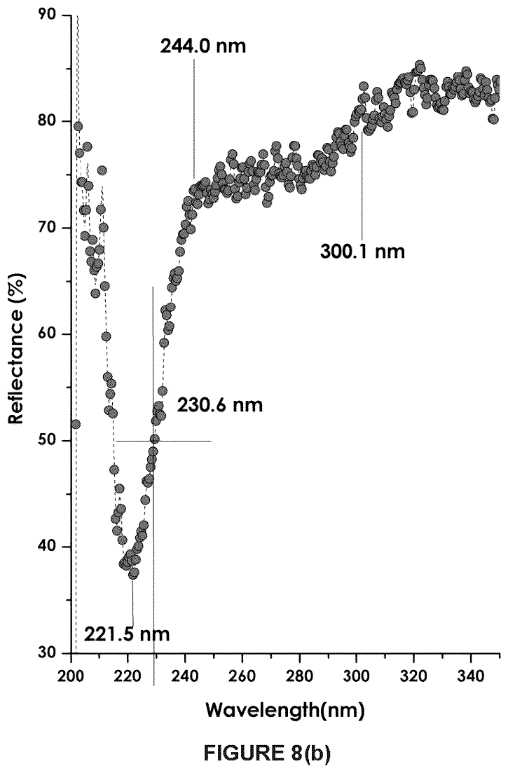

In regard to light scattering & white pigment applications, FIG. 8(a) displays the standard diffuse reflectance spectrum under normal incidence of the bioengineered CaCO3 nanoparticles (in their pelletised powder form) within the spectral range of 200-1000 nm. FIG. 8(b) further displays the corresponding zoom on the UV-Bleu spectral region of 200-345 nm, therefore such an elevated reflectivity within the visible (VIS) & Near infrared (NIR) solar spectral regions is a characteristic of highly reflecting solar materials equivalent to that of standard white pigments including BaSO4, ZnO & TiO2. In view of the aforementioned, one could safely conclude that the bio-engineered CaCO3 nanoparticles of the present invention could be a potential compound for white pigment coatings' applications.

In regard to nanofertilizing, Calcium is a crucial plant nutrient playing a vital role in maintaining plant cellular metabolism. As a biocatalyst becoming functional through Calcium ionic species, these Calcium ionic species are concerned with hydrocarbons metabolism, maintenance of cellular membranes, leaf morphology, physiology of membrane, protein production. In view of investigating the effectiveness of the currently bio-engineered CaCO3 nanoparticles, they were tested as a bio/nano-fertilizer in the case of Lycopersicum esculentum (Tomato). The concentration of the CaCO3 product of the present invention was fixed at a concentration of 0.01, 0.03 and 0.05 g/l and compared to the control. Accordingly, the average plant's height, the average number of leaves as well as the average number of days to flowering were collected. Experimental parameters were similar to the following publication: N.Jabeen, Q. Maqbool, T. Bibi, M. Nazar, S. Z. Hussain, T. Hussain, T. Jan, I. Ahmad, M. Maaza, S. Anwaar, Optimised synthesis of ZnO-nano-fertiliser through green chemistry: boosted growth dynamics of economically important L. esculentum, IET NanobiotechnologyVol. 12 Iss. 4, pp. 405-411 (2018).

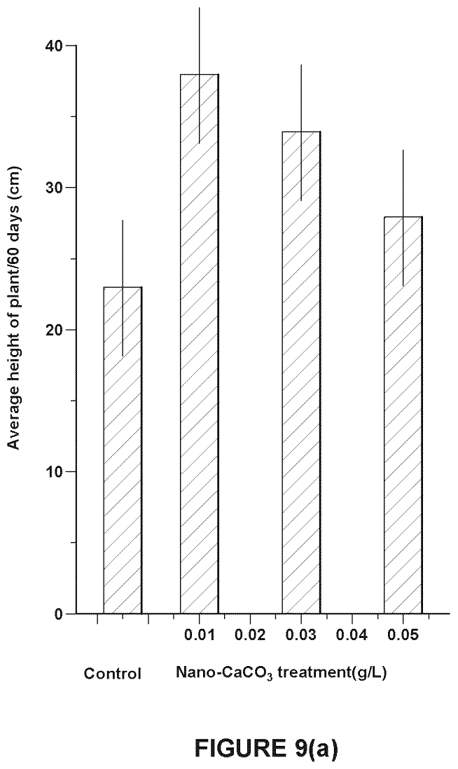

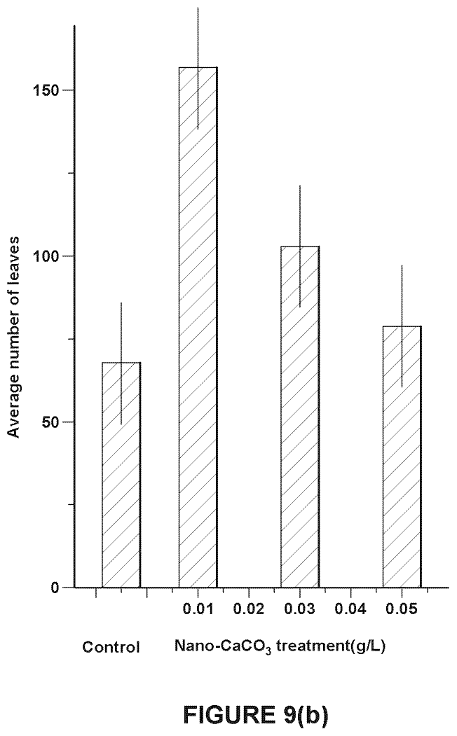

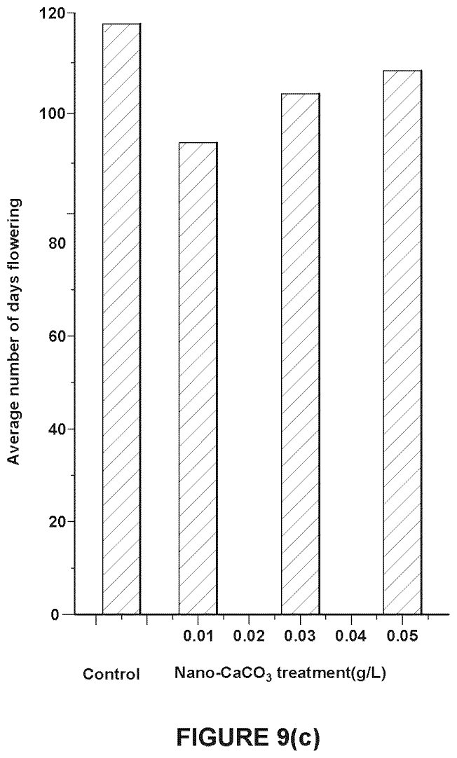

FIG. 9(a) displays the evolution of the average of plant's height versus the CaCO3 nutrient concentration. One conclusion is that the plant's height is higher than that of the control one for each of the CaCO3 nutrient's concentration especially for the lowest value of 0.01 g/l. A similar behaviour is observed for the average number of leaves vs nutrient concentration (FIG. 9(b). FIG. 9(c) seems to be of a special interest. It indicates that the average days to flowering is lower with the CaCO3 nutrient concentration relatively to the control sample. Especially for the 0.01 g/l, the flowering is 24 days before the control. As a pre-conclusion, the plant's growth parameters are far competitive relatively to the control especially for the lowest concentration of 0.01 g/l which seems the optimal value within these conditions of experimentation.

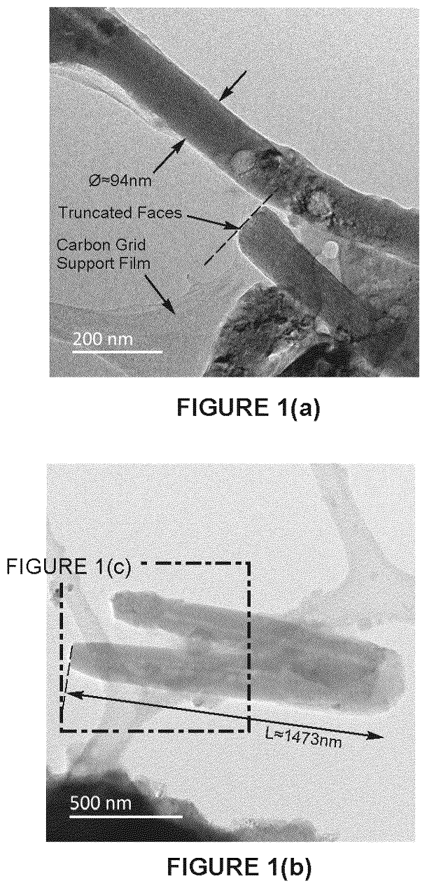

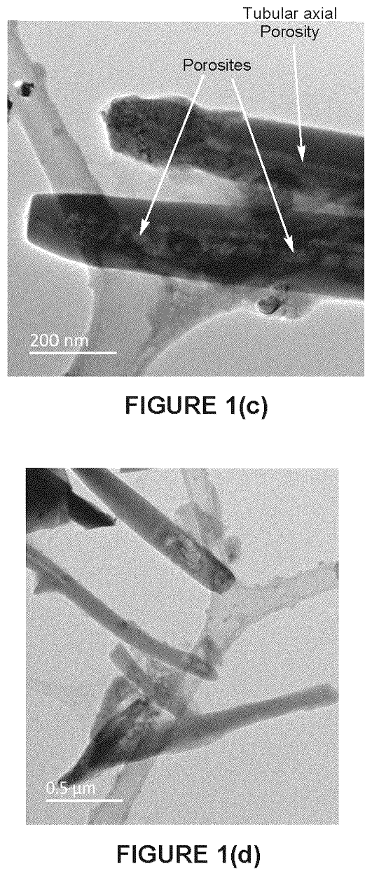

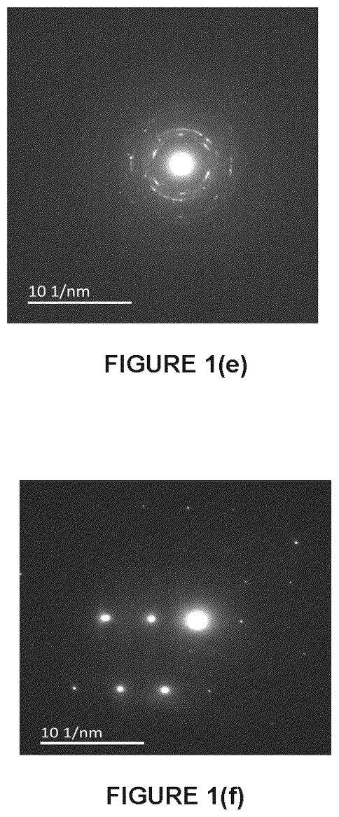

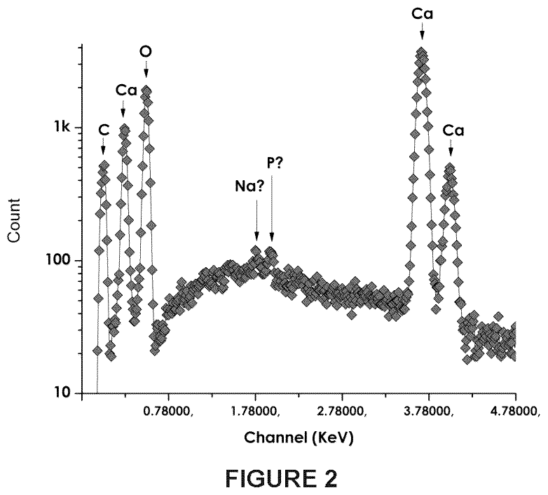

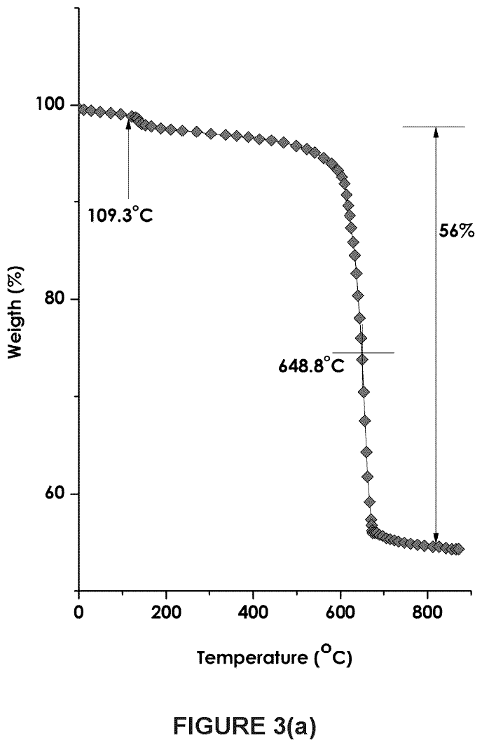

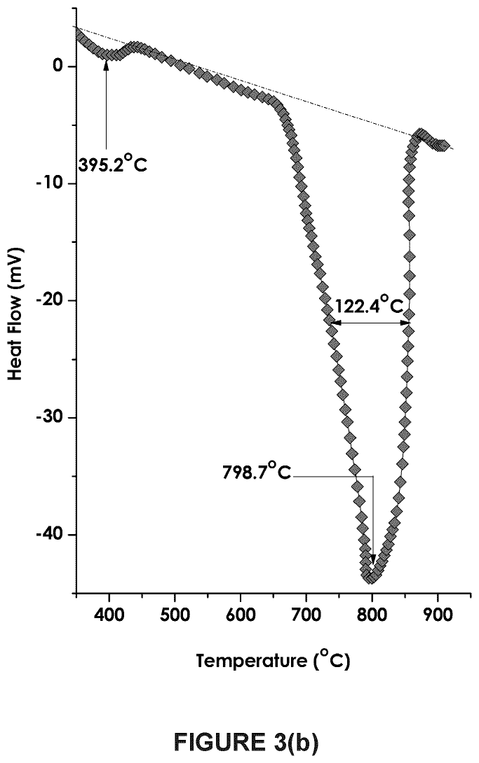

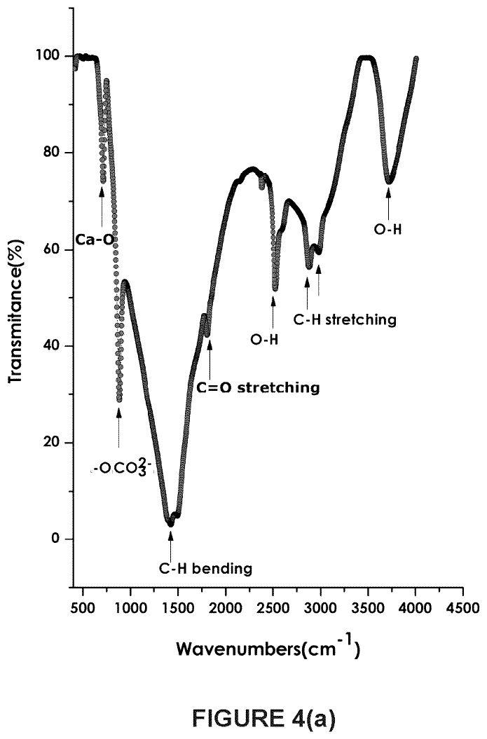

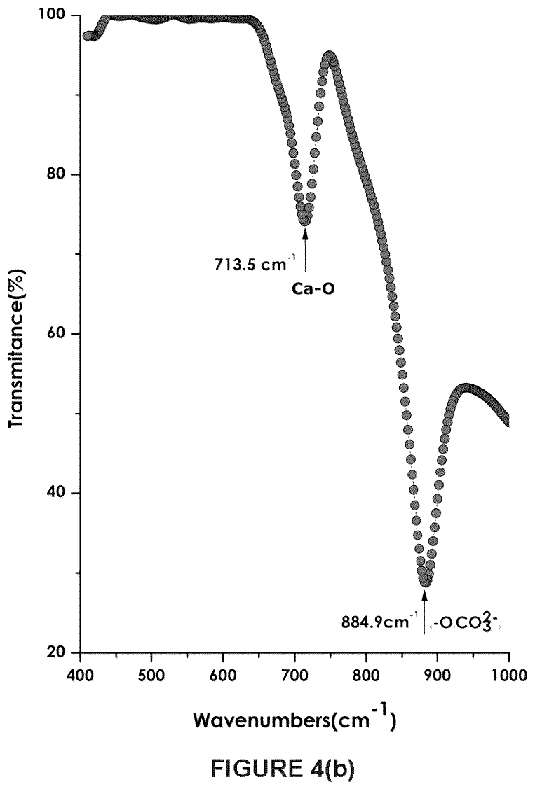

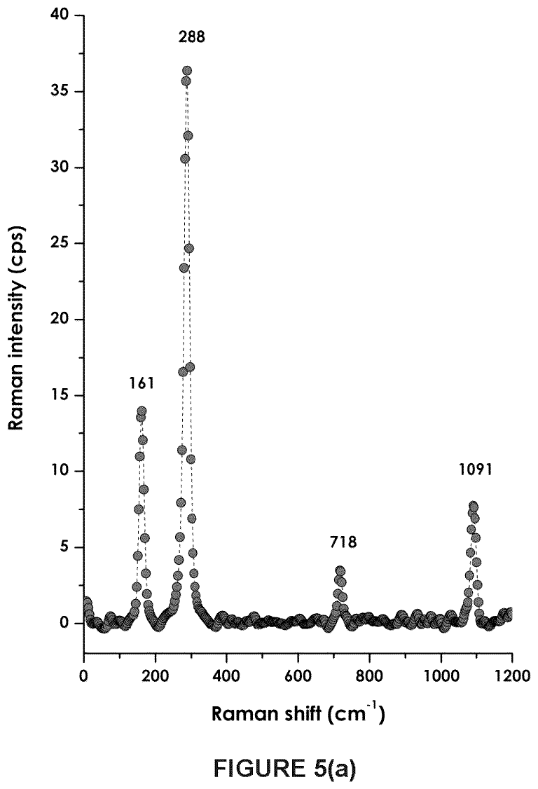

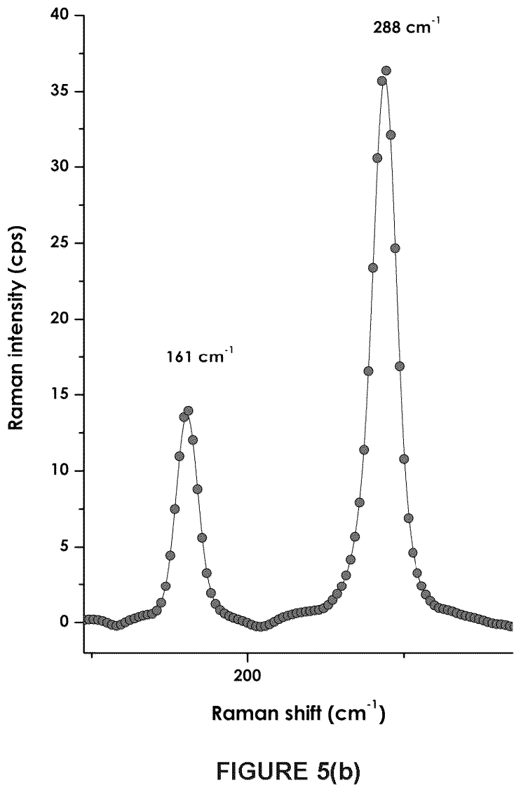

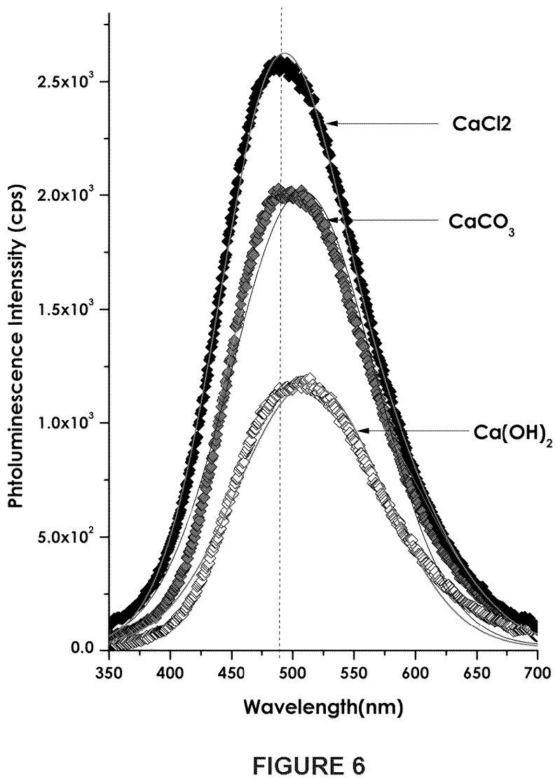

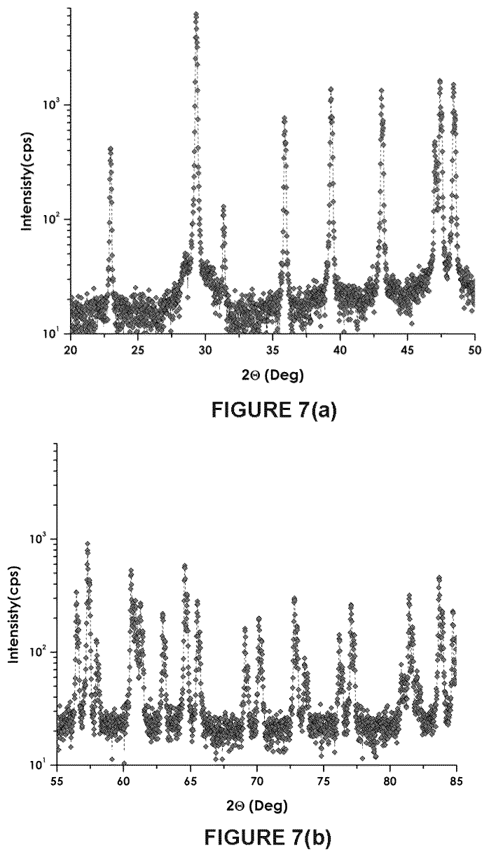

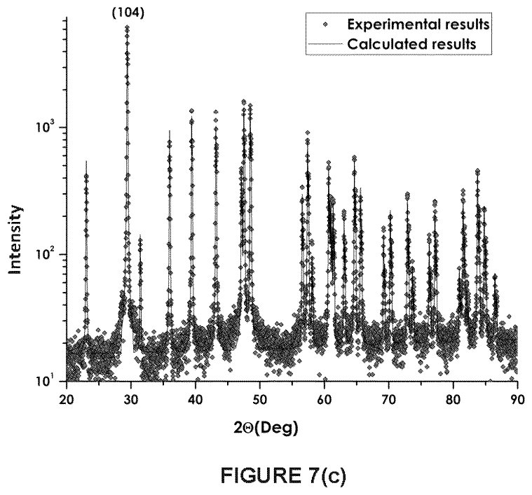

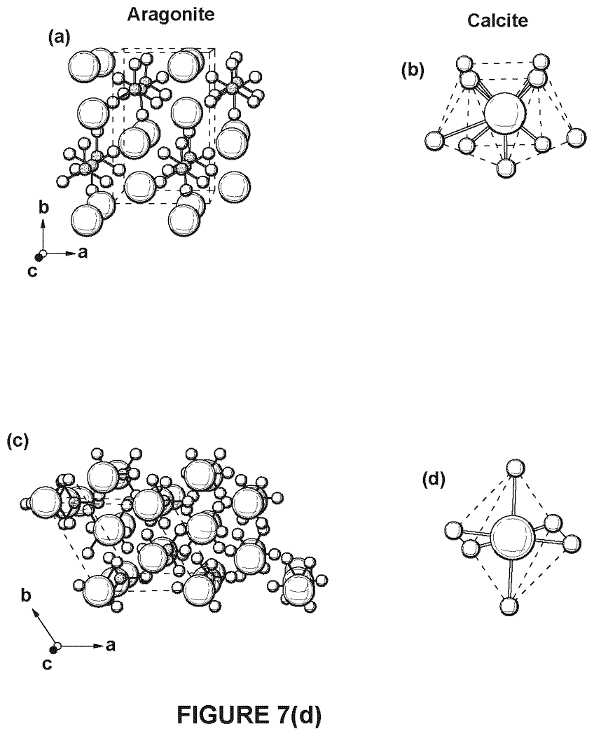

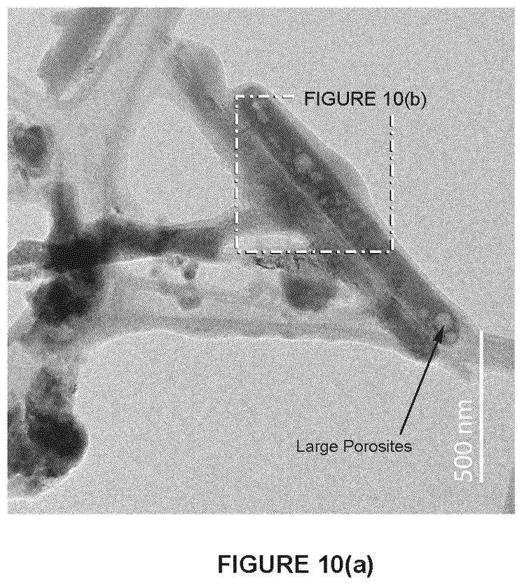

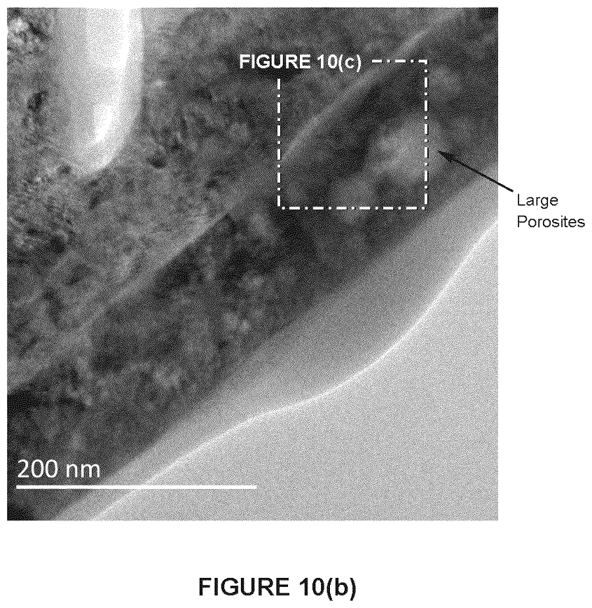

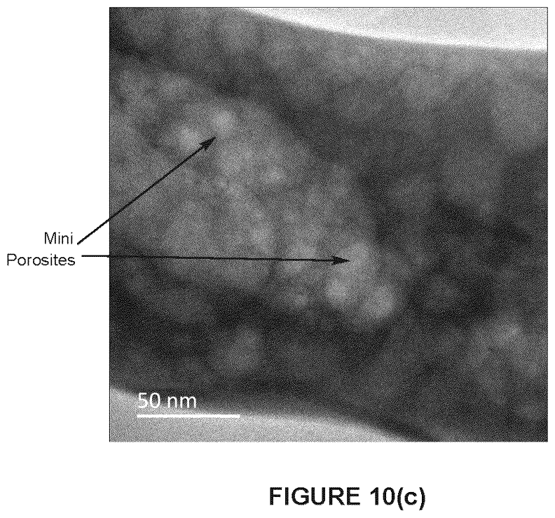

In regards to cement binder applications, As per FIGS. 1(a)-1(f), the bio-engineered CaCO3 is nano-scaled in size, and hence has a finer particles size as compared to the Ordinary Portland Cement (OPC) particles (which is in the range of 10 μm in average). This fine aspect would likely improve the particle packing of concrete and give a superior spacer effect. Also, the concrete with CaCO3 replacement as per the present invention possess a higher slump, which increases the workability. In addition, in a statistical spatial distribution, the 1-D morphology of the CaCO3 nanoparticles of the present invention would favour if not enhance the local mechanical strength of the CaCO3/Cement composite as a local reinforcer. Furthermore, the porosity of the CaCO3 nanorods (FIG. 10) could favour an enhanced binding in view of the high surface to volume of the individual porous CaCO3 nanorods of the present invention.

Furthermore, the general TGA & DSC variations/trends of the bio-engineered CaCO3 of the present invention are equivalent to that of bulk CaCO3 but with a significant shift to lower temperatures. More accurately, the decomposition and phase transition temperature are ˜648.8° C. instead of ˜750° C. for Bulk. This is likely due to the high surface to volume ratio of the current nanoscaled CaCO3 of the present invention comparatively to their bulk equivalent. This would improve its workability within the cement composite.

What is claimed is:

1. A process for the production of precipitated single-phase crystalline 1-D nanoscaled calcite (CaCO3), the process comprising:
providing a source of calcium cations;
providing a source of carbon dioxide (CO2);
providing a solvent in the form of water (H2O);
providing a natural extract obtained from a plant species as a chelating agent; and
extracting the precipitate,
wherein the natural extract is obtained from Hyphaene thebaica fruit.

2. The process of claim 1, wherein the calcium cations are obtained from calcium chloride (CaCl2) and wherein the calcium chloride (CaCl2) is added to a filtered extract solution and stirred for 24 hours at room temperature with gentle stirring.

3. The process of claim 1 further comprising adding CO2 via bubbling and allowing the precipitate to settle.

4. The process of claim 1, wherein the precipitate is collected by centrifugation for 10 to 30 minutes at 3,000 rpm to 5,000 rpm.

5. The process of claim 1 further comprising washing the precipitate thrice in deionized water (dH2O) and subsequent centrifugation for 5 to 15 minutes at 3,000 rpm to 5,000 rpm.

6. The process of claim 1, wherein no additional catalyst, chemicals for pH control, or thermal treatment is used during or after the biosynthesis process.

7. A product obtained by the process of claim 1 for use in cement binder applications.

8. A product obtained by the process of claim 1 for use as a nano-fertilizer.

9. A product obtained by the process of claim 1 for use as a drug carrier in the health sector.

10. A product obtained by the process of claim 1 for use as a white pigment.

11. The process of claim 1, wherein a resulting product is used in an emulsion stable in water for application to the surfaces of plants to provide sun blocking characteristics.

12. The process of claim 11, wherein the resulting product is diluted in water and applied to an area with a spraying device.

13. The process of claim 1, wherein the calcite has a high reflectivity within the visible (VIS) and Near Infrared (NIR) solar spectral regions.

14. The process of claim 1, wherein the calcite is tested as a bio/nano-fertilizer in the growth of Lycopersicum esculentum (Tomato), with the concentration of the CaCO3 product fixed at 0.01, 0.03, and 0.05 g/l.

15. The process of claim 1, wherein the bio-engineered CaCO3 nanorods improve the workability and mechanical strength of cement composites due to their fine particle size and porosity.
